(19) United States
(12) Patent Application Publication
(10) Pub. No.: US 2020/0413543 A1
(43) Pub. Date: Dec. 31, 2020

(54) MOLDED INDUCTOR COIL FOR SWITCHED-MODE POWER SUPPLY

(71) Applicant: Continental Automotive Systems, Inc., Auburn Hills, MI (US)

(72) Inventors: Christian Ignacio Morales Rodriguez, Tlajomulco de Zúñiga (MX); Tomas Valenzuela Castro, Guadalajara (MX); Josue Daniel Vazquez Rivas, Tlajomulco de Zúñiga (MX); Luis Javier Del Real Ibanez, Rochester, MI (US)

(73) Assignee: Continental Automotive Systems, Inc., Auburn Hills, MI (US)

(21) Appl. No.: 16/457,205

(22) Filed: Jun. 28, 2019

(51) Int. Cl. H05K 1/18

(52) U.S. Cl. CPC H05K 1/181; H05K 2201/10151; H05K 2201/1003

(57) ABSTRACT

An airbag control system includes a printed circuit board, a switched-mode power supply having a molded inductor electrically mounted on the printed circuit board, and at least one Micro-Electro-Mechanical System (MEMS) sensor electrically mounted on the printed circuit board.

### FIELD

The invention relates to inductors for Switched-Mode Power Supply (SMPS) system and, more particularly, to a molded inductor that reduces vibrations that affect sensitive components of the SMPS system.

### BACKGROUND

Conventional ferrite power inductors are typically used in a Switched-Mode Power Supply (SMPS) to generate specific voltages. The output voltage is generated by switching current through an inductor at a frequency defined by the configuration of the power supply. Inductors vibrate at SMPS frequencies (fundamental, modulation, and harmonic frequencies) due to electromagnetism. For applications using Micro-Electro-Mechanical System (MEMS) sensors, vibration of the conventional inductor that is transferred to the PCB can cause major disturbances to the sensor's operation.

Thus, there is a need to provide a molded inductor that reduces vibrations that affect sensitive system components.

### SUMMARY

An objective of the embodiment is to fulfill the need referred to above. In accordance with the principles of the embodiment, this objective is achieved by providing a switched-mode power supply system including a printed circuit board, and an inductor electrically mounted on the printed circuit board. The inductor includes coil structure encapsulated in molding material.

In accordance with another aspect of an embodiment, an airbag control system includes a printed circuit board, a switched-mode power supply having a molded inductor electrically mounted on the printed circuit board, and at least one Micro-Electro-Mechanical System (MEMS) sensor electrically mounted on the printed circuit board.

Other objectives, features and characteristics of the present embodiment, as well as the methods of operation and the functions of the related elements of the structure, the combination of parts and economics of manufacture will become more apparent upon consideration of the following detailed description and appended claims with reference to the accompanying drawings, all of which form a part of this specification.

### BRIEF DESCRIPTION OF THE DRAWINGS

The invention will be better understood from the following detailed description of the preferred embodiments thereof, taken in conjunction with the accompanying drawings, wherein like reference numerals refer to like parts, in which:

FIG. 1 is a schematic illustration of a SMPS system in the form of a step-up converter with a molded inductor in accordance with an embodiment.

FIG. 2 is a plan view of an airbag control system including the SMPS system of FIG. 1.

FIG. 3 is a FFT graph showing frequency domain of vibration measurements of a conventional ferrite inductor compared with that of the molded inductor of the embodiment.

### DETAILED DESCRIPTION OF EXAMPLE EMBODIMENTS

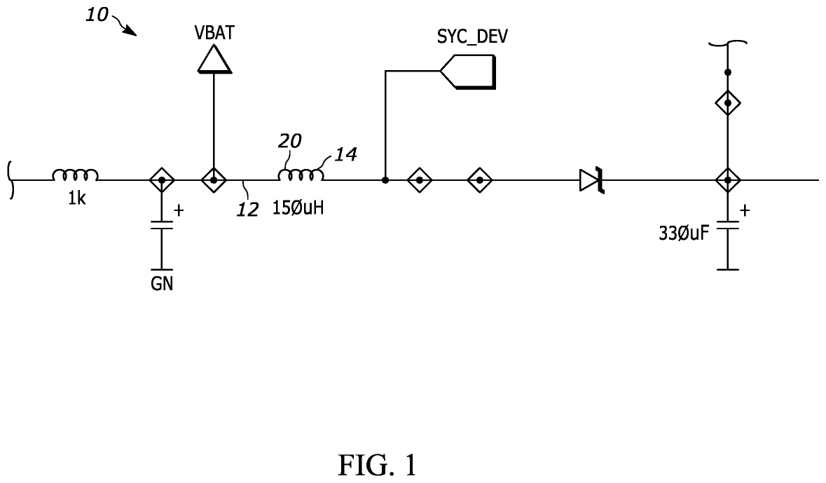

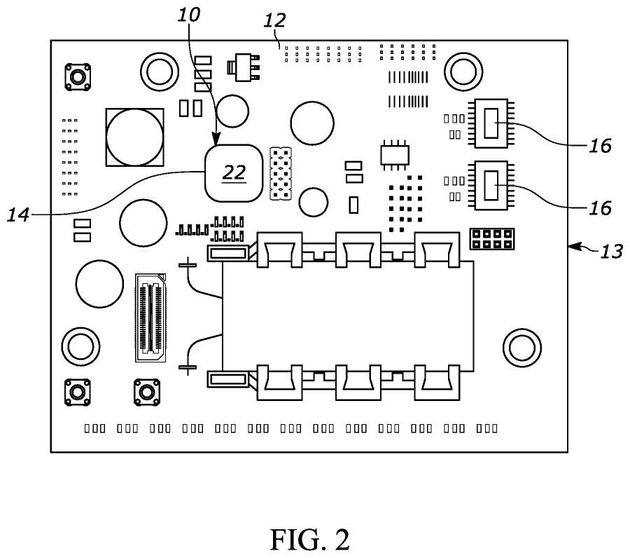

With reference to FIG. 1, a schematic illustration of a SMPS system is shown, generally indicated at 10, in accordance with an embodiment. FIG. 2 shows the system SMPS 10 mounted on a printed circuit board (PCB) 12 of a control system 13. The SMPS system 10 includes a molded inductor 14 electrically mounted on the PCB 12. The system 10 is preferably in the form of a step-up converter for an airbag control system 13 for a vehicle, but can be any system that requires an inductor 14 to generate specific voltages. In the embodiment, the SMPS system 10 generates 32V from the vehicle's 12V battery.

The inductor 14 can be of the type manufactured by Vishay, part number IHLP-4040DZ-ER-900-K-5A. Thus, the inductor 14 includes a coil structure 20 (FIG. 1) that is encapsulated in magnetic molding material 22 (FIG. 2). The molding material 22 preferably comprises powdered iron, a filler, a resin, and a lubricant, as disclosed in U.S. Pat. No. 6,460,244, the contents of which is hereby incorporated by reference herein.

The control system 13 includes at least one sensor 16 electrically mounted on the PCB 12. The sensor 16 is preferably a MEMS sensor such as an inertial sensor for use in air bag deployment.

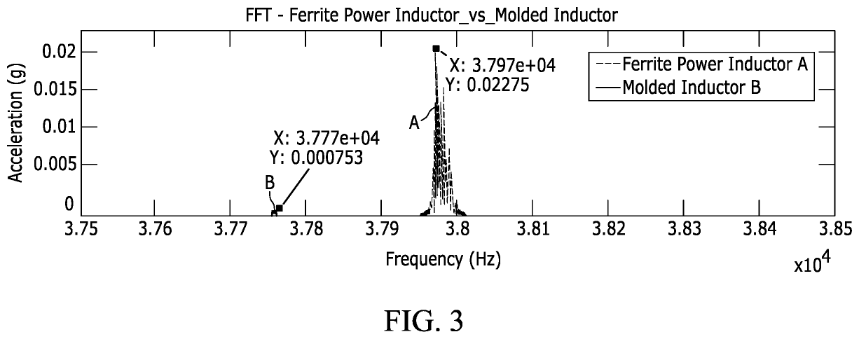

A conventional ferrite inductor was first employed in the SMPS system 10 of FIG. 2 and was tested and then was replaced with the molded inductor 14 of the embodiment and was then re-tested. FIG. 3 is a fast Fourier transform (FFT) graph showing the frequency domain of vibration measurements of the tested conventional ferrite inductor A compared with the measurements B of the tested molded inductor 14 of the embodiment. As can be seen, use of the molded inductor 14 instead of the conventional ferrite inductor results in thirty times reduction of vibration in the SMPS system 10 and thus the sensors 16, mounted on the common PCB 12, are exposed to significantly less vibrational disturbance. Thus, a wider range of MEMS sensors can be used in the control system 13. Also, using the molded inductor 14 in the SMPS system 10 does not result in additional manufacturing process.

The foregoing preferred embodiments have been shown and described for the purposes of illustrating the structural and functional principles of the present invention, as well as illustrating the methods of employing the preferred embodiments and are subject to change without departing from such principles. Therefore, this invention includes all modifications encompassed within the spirit of the following claims.

What is claimed is:

1. A switched-mode power supply system comprising:
a printed circuit board, and
an inductor electrically mounted on the printed circuit board, the inductor including coil structure encapsulated in molding material.

2. The switched-mode power supply system of claim 1, wherein the molding material comprises at least powdered iron and a resin.

3. The switched-mode power supply system of claim 1, in combination with at least one sensor electrically mounted on the printed circuit board.

4. The switch-mode power supply of claim 3, wherein the at least one sensor includes a Micro-Electro-Mechanical System (MEMS) sensor.

5. The switched-mode power supply system of claim 4, wherein the at least one MEMS sensor is an inertial sensor.

6. The switched-mode power supply system of claim 1, wherein the system is a step-up converter that is constructed and arranged to generate 32V from a vehicle's 12V battery.

7. An airbag control system comprising:
a printed circuit board,
a switched-mode power supply comprising a molded inductor electrically mounted on the printed circuit board, and
at least one Micro-Electro-Mechanical System (MEMS) sensor electrically mounted on the printed circuit board.

8. The airbag control system of claim 7, wherein the molded inductor includes coil structure encapsulated by molding material that comprises at least powdered iron and a resin.

9. The airbag control system of claim 7, wherein the at least one MEMS sensor is an inertial sensor.

10. The airbag control system of claim 7, wherein the switched-mode power supply system is a step-up converter that is constructed and arranged to generate 32V from a vehicle's 12V battery.
